(19) United States
(12) Patent Application Publication
(10) Pub. No.: US 2018/0065577 A1
(43) Pub. Date: Mar. 8, 2018

(54) OPTIMIZATION METHOD AND APPARATUS OF POWER CONTROL LOGIC FOR ENTERING INTO ISG MODE

(71) Applicants: Hyundai Motor Company, Seoul (KR); Kia Motors Corporation, Seoul (KR)

(72) Inventor: Young-Kug LEE, Hwaseong-si (KR)

(21) Appl. No.: 15/368,056

(22) Filed: Dec. 2, 2016

(30) Foreign Application Priority Data
Sep. 6, 2016 (KR) 10-2016-0114354

(51) Int. Cl. B60R 16/033; B60Q 1/04; G01R 31/36

(52) U.S. Cl. CPC B60R 16/033; G01R 31/3693; B60Q 1/04

(57) ABSTRACT

An optimization method of a power control logic for entering into an idle stop & go (ISG) mode comprises steps of: monitoring a state of charge (SOC) of a battery to detect a parasitic current of the battery by a battery sensor of a vehicle; transmitting a parasitic current flag to an engine control unit (ECU) when the battery sensor detects the parasitic current; and determining whether a device using standby power of the battery is installed and increasing a voltage of the battery via additional power control when it is determined that the device is installed.

### CROSS-REFERENCE TO RELATED APPLICATION

This application claims the benefit of priority to Korean Patent Application No. 10-2016-0114354, filed on Sep. 6, 2016 in the Korean Intellectual Property Office, the entire disclosure of which is incorporated herein by reference.

### TECHNICAL FIELD

The present disclosure relates to an optimization method and apparatus of a power control logic, and more particularly, to an optimization method and apparatus of a power control logic for entering into an idle stop & go (ISG) mode.

### BACKGROUND

Recently, a significant amount of research has been conducted to improve fuel efficiency in the transportation field in response to increases in oil price, as well as global warming caused by the production of carbon dioxide. An idle stop & go (ISG) system applied initially to a hybrid vehicle has been extensively applied to all types of vehicles in order to improve fuel efficiency around the world. An ISG system refers to an engine control system that automatically stops an engine when the engine is running idle while, for example, the vehicle stops due to waiting for a traffic signal during driving in a section of a city. The ISG system then restarts the engine when the vehicle intends to drive after a predetermined time period to enable normal driving. The ISG system may also be represented by an idle running stop control device or the like, and a vehicle including the ISG system installed therein may be referred to as an ISG vehicle.

A condition for entrance into engine starting stop by an ISG system is a condition in which a transmission gear is maintained in a control state of D for drive, a brake pedal is operated, and a preset predetermined time period is maintained in a stop state in which vehicle speed is not detected, and in this case, an engine may be stopped to increase fuel efficiency. On the other hand, when an operation of an acceleration pedal is detected in a state in which the engine is stopped and a driver departure request from which release of the brake pedal is detected is detected, the engine may be restarted so as to maintain normal driving.

In this regard, Korean Patent Publication No. 2012-0063401 (Method and Apparatus for controlling ISG logic) discloses a method and apparatus for controlling ISG logic, for ensuring launching performance and ensuring stable starting of an ISG vehicle by controlling the ISG vehicle to maintain an oil pressure of a transmission even in an idle stop state and controlling RPM of an engine and an oil pressure of a brake during restart of the vehicle.

However, along with an increase in the number of external electronic devices such as a dashcam using standby power, a battery is maintained in a discharging state and a battery state condition for an ISG operation is not satisfied.

### SUMMARY

Therefore, the present disclosure has been made in view of the above problems of the related art, and it is one object of the present disclosure to provide an optimization method and apparatus for entrance into ISG mode via charging for a short time even if devices using standby power are connected.

In addition, it is another object of the present disclosure to provide an optimization method and apparatus for preventing overvoltage of other peripheral devices when a charged amount of a battery is changed in order to enter an ISG state.

Technical objects to be achieved by the present disclosure are not limited to those mentioned above, and other objects may be clearly understood by those skilled in the art from the description given below.

In accordance with the present disclosure, the above and other objects can be accomplished by the provision of an optimization method of a power control logic for overcoming an issue in terms of non-entrance into idle stop & go (ISG) mode. The method includes steps of monitoring a state of charge (SOC) of a battery to detect a parasitic current of the battery by a battery sensor of a vehicle, transmitting a parasitic current flag to an engine control unit (ECU) when the battery sensor detects the parasitic current, and checking whether a device using standby power of the battery is installed and increasing a voltage of the battery via additional power control upon checking that the device is installed.

The device may be a dashcam connectable to a vehicle to which an ISG logic is applied.

The method may further include, prior to the monitoring, a step of entering a control logic for preventing additional power control when a headlamp of the vehicle is turned on. The control logic may control increase in a voltage of the headlamp to prevent the headlamp from being damaged due to overvoltage.

Whether the headlamp is turned on may be checked before checking whether another peripheral device capable of increasing a voltage in the vehicle is also installed, and the entrance into the control logic may be prevented when the headlamp is turned on.

The parasitic current flag may be transmitted to the ECU via a local interconnect network (LIN) communication method. The checking may include checking whether the battery is discharged due to the device, and comparing the SOC of the battery with a preset reference value. When the SOC of the battery is less than the preset reference value, voltage increase may be executed and information on the execution may be transmitted to a customer of the vehicle.

In the step of checking whether the device is installed, the voltage increase may not be performed when it is determined that the device is not installed.

The method may further include, after the step of checking whether the device using standby power of the battery is installed, terminating the additional power control and determining whether ISG is released, wherein the vehicle may maintain a state prior to restarting for entrance into the ISG mode.

In accordance with the present disclosure, the above and other objects can be accomplished by the provision of an optimization apparatus of a power control logic for overcoming an issue in terms of non-entrance into idle stop & go (ISG) mode. The apparatus includes a battery sensor for monitoring a state of charge (SOC) of a battery installed in the vehicle to detect a parasitic current of the battery and generating and transmitting a parasitic current flag according to generation of the parasitic current, a device using standby power of the battery, and an engine control unit (ECU) for checking the device and increasing a voltage of the battery via additional power control.

It is one object of the present disclosure to provide an optimization method and apparatus for entrance into ISG via charging for a short time even if devices using standby power are connected.

In addition, it is another object of the present disclosure to provide an optimization method and apparatus, for preventing overvoltage of other peripheral devices when a charged amount of a battery is changed in order to enter an ISG state.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a diagram illustrating a structure of an optimization apparatus of a power control logic according to an exemplary embodiment;

FIG. 2 is a flowchart of an optimization method of a power control logic according to an exemplary embodiment; and

FIG. 3 is a flowchart illustrating subdivided operations of a power control logic according to an exemplary embodiment.

FIG. 4 is a diagram showing a LIN bus using a master/slave method using a LIN master and one or more LIN slaves.

### DETAILED DESCRIPTION OF THE EMBODIMENTS

Hereinafter, the present disclosure will be described in detail with reference to the accompanying drawings to allow those skilled in the art to easily practice the present disclosure. However, the present disclosure may be embodied in many different forms and is not limited to the exemplary embodiments described herein. In the drawings, to clearly describe the exemplary embodiments, the same or similar elements are denoted by the same reference numerals even though they are depicted in different drawings.

The objectives and advantages of the exemplary embodiments of the present invention will be understood and more obvious with reference to the following description and are not limited to the following description. In the description of the exemplary embodiments, certain detailed explanations of the related art are omitted when it is deemed that they may unnecessarily obscure the essence of the present disclosure.

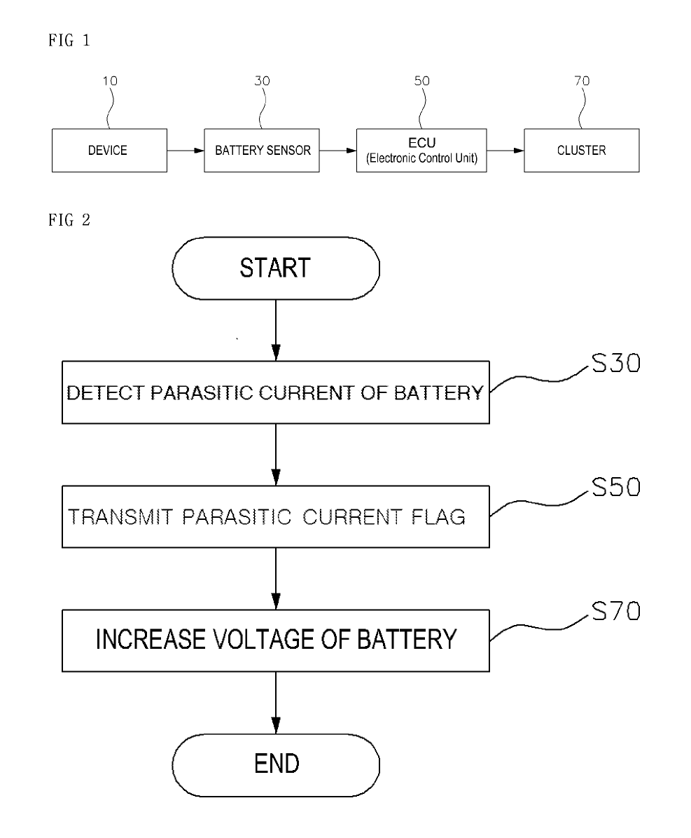

FIG. 1 is a diagram illustrating a structure of an optimization apparatus 1 of a power control logic according to an exemplary embodiment. Referring to FIG. 1, the optimization apparatus 1 of the power control logic may include a device 10, a battery sensor 30, an engine control unit (ECU) 50, and a cluster 70.

The device 10 may use standby power of a battery and may be a dashcam that is connectable to a vehicle to which idle stop & go (ISG) logic is applied. Generally, the ISG may be a technology for restricting idle running, which is a state in which the vehicle is turned on but is not driving. A vehicle consumes fuel and discharges exhaust gas because the engine is operated while running idle as well as driving. Accordingly, as running idle is frequently performed, fuel consumption may be increased and fuel efficiency may be reduced.

The ISG is operated by a battery and, thus, when a dashcam using standby power is connected to the vehicle, the vehicle is not turned off and, in this regard, the present technology overcomes this issue. When a dashcam is installed in the vehicle, a lifetime of a battery is rapidly reduced, and, in this regard, the present technology is advantageous in that this issue is overcome by applying full charge logic.

The battery sensor 30 may monitor a charging state of a battery installed in a vehicle, detect a parasitic current of the battery, and generate and transmit a parasitic current flag according to whether parasitic current is generated. Parasitic current refers to current consumed in devices that are operated using power of a battery even if a vehicle is turned off and, for example, a radio, an ECU, or the like may use a parasitic current.

The ECU 50 may check the device 10 and increase a voltage of the battery via additional power control. The general ECU 50 may refer to a device that controls a state of a vehicle engine, an automatic transmission, an ABS, or the like using a computer.

The cluster 70 may refer to a dashboard displaying driving information to a user and notify a driver of speed, mileage, a fuel consumption state, and so on so as to support stable driving.

A parasitic current flag may indicate a parasitic current state, that is, power consumed in electric components installed in a vehicle as the reason for parasitic current as described above, and indicate information on leakage current due to a dashcam, a bidirectional remote controller, an embedded navigation device, an audio device, and so on. In this regard, according to an exemplary embodiment, a parasitic current flag may be generated and transmitted as a solution to parasitic current.

Hereinafter, an optimization method of a power control logic for entering into an ISG mode using the aforementioned optimization apparatus 1 of a power control logic will be described.

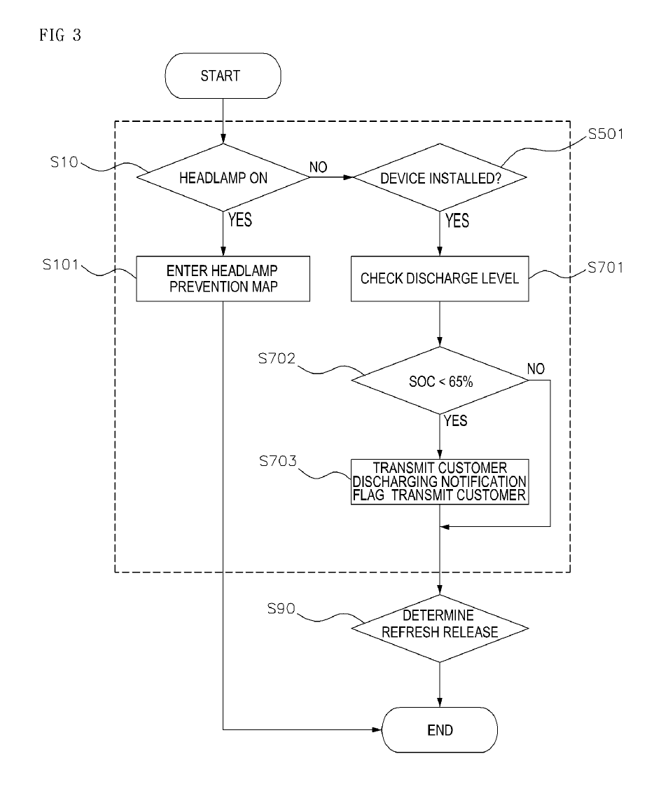

FIG. 2 is a flowchart of an optimization method of a power control logic according to an exemplary embodiment in the present disclosure. Referring to FIG. 2, the optimization method of a power control logic may include:

detecting a parasitic current of a battery (S30); transmitting a parasitic current flag (S50); and increasing a voltage of the battery (S70).

The step of detecting a parasitic current of the battery (S30) may be initiated while a battery sensor is monitoring a battery charging state. As described above, the device 10 or the like may be connected using parasitic current and, in this case, standby power may be consumed. In addition, when the amount of leakage current is greater than normal current due to wire bonding or poor wiring due to deterioration of a vehicle, parasitic current may be detected. The reason for measurement of parasitic current is related to discharging time of a battery and, in this case, when a discharged amount is high, battery output may be weak and restart may be affected and, thus, detection of parasitic current may cause a significant improvement in the operation of the vehicle.

The step of transmitting a parasitic current flag (S50) may refer to an operation of indicating a current state to the ECU 50 when a battery charging state is less than a reference value or a discharging amount is high. In this case, transmission to the ECU 50 from the battery sensor 30 may use local interconnect network (LIN) communication. LIN communication is a low-cost embedded networking standard that is most universally used in a vehicle field for connection with intelligent devices.

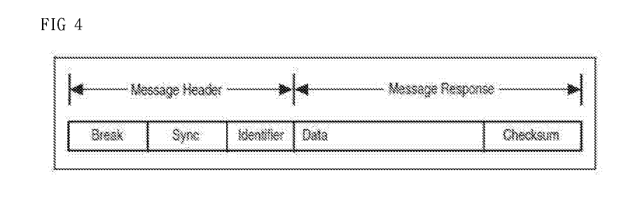

A LIN bus may use a master/slave method using a LIN master and one or more LIN slaves as shown in FIG. 4. A message header may include a field ‘Break’ used to recognize start of a frame, a field ‘Sync’ used in a slave node for clock synchronization, and an identifier (ID) including a 6-bit message ID and a 2-bit parity field. The ID may indicate a specific message address but may not indicate a destination and, when the ID is received and interpreted, one slave may start message response. The message response may include 1 to 8 bytes of data and 8-bit checksum, a master may control sequencing of a message frame fixed to schedule and, as necessary, the schedule may be changed.

The step of increasing a voltage of the battery (S70) may refer to an operation in which the ECU 50 checks whether the device 10 using standby power of the battery is installed and increases the voltage of the battery via additional power control when the device 10 is checked.

The method may further include: prior to the first operation (S30), when a headlamp of a vehicle is turned on (S10), a step of entering a control logic for preventing additional power control (S101). The control logic of this operation may control increase in a voltage of the headlamp to prevent the headlamp from being damaged due to overvoltage.

Additional power control may refer to an operation of recognizing that battery charging is poor and increasing an output voltage of the battery when the aforementioned parasitic current flag is transmitted to the ECU 50.

According to an exemplary embodiment, in the case of 14.3 V or less, a parasitic current flag may be transmitted, and a voltage may be increased up to 15 V within a current limited range of 50 A and, in this case, may be increased up to an output voltage appropriate for restarting.

FIG. 3 is a flowchart illustrating subdivided operations of a power control method according to an exemplary embodiment. Referring to FIG. 3, prior to a first operation, whether a headlamp is turned on may be checked (S10). The headlamp may bechecked before checking whether a peripheral device, such as a wiper, which are also capable of increasing a voltage in a vehicle, is operated.

Whether the headlamp is turned on may be checked in order to lower the possibility of a side effect such as lamp damage or a decrease in fuel efficiency, and to increase a charging voltage when an overvoltage occurs in a voltage applied to the headlamp due to increase in voltage.

The step of increasing a voltage of the battery (S70) may include: a first operation (S501) of checking whether the device 10 is installed; a second operation (S701) of checking whether the battery is discharged due to the device 10; and a third operation (S702) of comparing a state of charge (SOC) of the battery with a preset reference value.

The present disclosure proposes a solution for an issue in terms of non-entrance into the ISG mode when the device 10 is installed and, thus, the first operation (S501) of checking whether the device 10 is installed may refer to an operation that is required because the current operation is meaningless if the device 10 is not installed. In the first operation (S501) of checking whether the device 10 is installed, when whether the device 10 is installed is not checked, a voltage may not be increased. Accordingly, when the device 10 is not installed, the method may proceed like a conventional method.

The second operation (S702) of checking whether the battery is discharged due to the device 10 may refer to an operation of previously checking whether an additional power control logic for increase in a voltage is necessary, as described above. When a voltage required for restarting of a vehicle is charged, the additional power control logic may not be driven.

The step of checking an SOC of a battery (S702) may also be related to the aforementioned additional power control logic.

The method may further include, after the third operation (S70), a step of terminating the additional power control and determining whether ISG is released (S90), and a vehicle may maintain a state prior to entrance into the ISG mode.

The ECU 50 may execute voltage increase and transmit a customer notification flag to a vehicle customer (the cluster 70, etc.) via a controller area network (CAN) communication.

CAN communication refers to a type of network that is developed according to an environment in which more electronic devices are executed in a vehicle, user demand for low fuel consumption, low exhaust gas, and convenience and safety, and corresponding necessity of a vehicle network.

CAN was originally developed for a vehicle and, thus, a most common application is in-vehicle electronic networking. As the safety and advantages of CAN for applications other than vehicles have been proved over 15 years, a CAN bus has also been applied to broad applications in other fields. For example, CAN has been applied to applications for a train (a tram, a subway, a light rail, and a long-distance train). CAN may also be used in another level of various networks in a vehicle and may also be applied to an aircraft application such as an aircraft state sensor, a navigation system, and a research PC in a flight deck. In addition, the CAN bus may also be used in various aerospace applications to an engine control system (a fuel system, a pump, a linear actuator, etc.) from in-flight data analysis.

Although exemplary embodiments of the present disclosure have been described for illustrative purposes, those skilled in the art will appreciate that various modifications, additions and substitutions are possible, without departing from the scope and spirit of the invention as disclosed in the accompanying claims.

What is claimed is:

1. An optimization method of a power control logic for entering into an idle stop & go (ISG) mode, the method comprising steps of:
monitoring a state of charge (SOC) of a battery to detect a parasitic current of the battery by a battery sensor of a vehicle;
transmitting a parasitic current flag to an engine control unit (ECU) when the battery sensor detects the parasitic current; and
determining whether a device using standby power of the battery is installed and increasing a voltage of the battery via additional power control when it is determined that the device is installed.

2. The method according to claim 1, wherein the device is a dashcam.

3. The method according to claim 1, further comprising, prior to the step of monitoring the SOC of the battery, a step of entering a control logic for preventing additional power control when a headlamp of the vehicle is turned on,
wherein the control logic controls an increase in a voltage of the headlamp to prevent the headlamp from being damaged due to overvoltage.

4. The method according to claim 3, wherein whether the headlamp is turned on is checked before checking whether another peripheral device capable of increasing a voltage in the vehicle is operated, and the entrance into the control logic is prevented when the headlamp is turned on.

5. The method according to claim 1, wherein the parasitic current flag is transmitted to the ECU via a local interconnect network (LIN) communication method.

6. The method according to claim 1, wherein the step of determining whether the device is installed comprises steps of: checking whether the battery is discharged due to the device; and comparing the SOC of the battery with a reference value,
wherein, when the SOC of the battery is less than the reference value, voltage increase is executed and information on the execution is transmitted to a customer of the vehicle.

7. The method according to claim 6, wherein, in the step of checking of whether the device is installed, the voltage increase is not performed when it is determined that the device is not installed.

8. The method according to claim 1, further comprising, after the checking of whether the device using standby power of the battery is installed, a step of terminating the additional power control and determining whether ISG is released,
wherein the vehicle maintains a state prior to restarting for entrance into the ISG mode.

9. An optimization apparatus of a power control logic for overcoming an issue in terms of non-entrance into an idle stop & go (ISG) mode, the apparatus comprising:
a battery sensor for monitoring a state of charge (SOC) of a battery installed in the vehicle to detect a parasitic current of the battery and generating and transmitting a parasitic current flag when the parasitic current is detected;
a device using standby power of the battery; and
an engine control unit (ECU) for checking the device and increasing a voltage of the battery via additional power control.
